(19) United States
(12) Patent Application Publication
(10) Pub. No.: US 2022/0199884 A1
(43) Pub. Date: Jun. 23, 2022

(54) THERMOELECTRIC DEVICE

(71) Applicant: AGENCY FOR SCIENCE, TECHNOLOGY AND RESEARCH, Singapore (SG)

(72) Inventors: Xizu WANG, Singapore (SG); Siew Lay LIM, Singapore (SG); Qiang ZHU, Singapore (SG); Jian Wei XU, Singapore (SG)

(21) Appl. No.: 17/603,883

(22) PCT Filed: Apr. 14, 2020
(86) PCT No.: PCT/SG2020/050229

§ 371 Date: Oct. 14, 2021

(30) Foreign Application Priority Data
Apr. 15, 2019 (SG) 10201903368Y

(51) Int. Cl. H01L 35/32; H01L 35/24; H01L 35/22

(52) U.S. Cl. CPC H01L 35/32; H01L 35/22; H01L 35/24

(57) ABSTRACT

Thermoelectric module (200, 300) comprising: a substrate (201); a first material (205) of a first doping type forming a first leg extending on a surface of the substrate (201), the first leg comprising a first end oriented towards a first region of the surface and a second, opposite end oriented towards a second region of the surface; and a second material (203) of a second doping type forming a second leg extending on the surface of the substrate (201), the second leg comprising a first end oriented towards the first region of the surface and a second, opposite end oriented towards the second region of the surface, such that the first and second legs are substantially parallel to each other, wherein the first end of the first leg is in electrical connection with the first end of the second leg, and wherein the first and second doping types have opposite polarity, such that when a heat flux (209) is applied between the first region and the second region of the surface, a potential difference arises between the second end of the first leg and the second end of the second leg, and wherein the substrate (201), the first material (205), and the second material (203) are substantially transparent to visible light.

### CROSS REFERENCE TO RELATED APPLICATION

The present disclosure claims the benefit of Singapore Patent Application No. 10201903368Y filed on 15 Apr. 2019, which is incorporated in its entirety by reference herein.

### TECHNICAL FIELD

The present disclosure relates to solid state devices, specifically solid-state thermoelectric modules.

### BACKGROUND

A thermoelectric generator (TEG), also called a Seebeck generator, is a solid-state device that converts heat flux (temperature difference) directly into electrical energy through a phenomenon called the Seebeck effect (a form of thermoelectric effect). In such generators, the charge flow stimulated across dissimilar materials due to heat gradients is exploited in order to generate an electromotive force.

FIG. 1 shows an example of a commercial design of a TEG module 100. The TEG module 100 comprises an electrically insulating substrate 100 on which are arranged N-type 103 and p-type 105 thermoelements joined by electrically conductive bridges 107. When a heat flux 109 is applied vertically, i.e. orthogonally to the plane of the substrate, a potential difference generated across electrodes attached to the thermoelements (not shown).

The thermoelectric energy conversion efficiency of a thermoelectric generator (TEG) primarily depends upon electrical conductivity, Seebeck coefficient and thermal conductivity of the materials from which it is constructed as well as the temperature difference between the hot source and the cold side of the thermoelectric module 100.

Recently, new thermoelectric materials and their corresponding devices for thermoelectric energy conversion in the low temperature range (room temperature 200° C.) have attracted a great deal of interest. These thermoelectric devices could be potentially used for consumer electronics, solar cells, home heaters, architectural structures, vehicles and wearable devices on human bodies that operate in the low temperature range. However, existing thermoelectric generators are typically based on bulk materials which makes them difficult to integrate into consumer electronics due to their size.

There is a need to provide improved thermoelectric modules for integration into consumer electronics.

### SUMMARY

In an aspect, a thermoelectric module is provided comprising: a substrate; a first material of a first doping type forming a first leg extending on the surface of the substrate, the first leg comprising a first end oriented towards a first region of the surface and a second, opposite end oriented towards a second region of the surface; and a second material of a second doping type forming a second leg extending on the surface of the substrate, the second leg comprising a first end oriented towards the first region of the surface and a second, opposite end oriented towards the second region of the surface, wherein the first end of the first leg is in electrical connection with the first end of the second leg, and wherein the first and second doping types have opposite polarity, such that when a heat flux is applied between the first region and the second region of the surface, a potential difference arises between the second end of the first leg and the second end of the second leg, and wherein the substrate, the first material, and the second material are substantially transparent to visible light.

As all the materials of the module are transparent, the overall module is transparent. This facilitates the integration of the thermoelectric module into consumer electronics as it can be integrated without altering the overall appearance of the electronic device. The visible light transmittance of the materials may be over 50%.

The term leg is merely intended to imply a portion of the respective material that extends in a particular direction on the surface of the substrate from one point (the first end of the respective leg) to another (the second end of the respective leg).

The first and second legs may comprise elongate portions of the first and second materials, respectively.

The first and second materials may comprise further portions in addition to the first and second legs.

The first and second legs may be in spaced parallel arrangement.

The first region and the second region of the surface may be opposite ends of the surface of the substrate. The first region and the second region of the surface may be opposite edges of the surface.

The first material may be a p-type material. The second material may be an n-type material. The first material may be a p-type thermoelectric material. The second material may be a n-type thermoelectric material.

The substrate may be substantially planar. The first material may be substantially planar. The first leg may be substantially planar. The second material may be substantially planar. The second leg may be substantially planar. The first material may comprise a thin-film material. The second material may comprise a thin-film material.

The thermoelectric module may be substantially planar. The overall profile of the thermoelectric module may be substantially planar.

A planar profile is advantageous as it facilitates integration of the module into electronic devices as it does not contribute to the overall bulk of the device.

The first end of the first leg and the first end of second leg may be in electrical connection via a direct interface between the first material and the second material. Equivalently, the first leg and the second leg may be in head-to-head connection.

This reduces the number of components in the device therefore reduces manufacturing complexity.

The first end of the first leg and the first end of the second leg may be in electrical connection via an electrical bridge between the first material and the second material. The electrical bridge may be metallic. The electrical bridge may be substantially planar. The electrical bridge may be substantially transparent to visible light.

An electrical bridge increases tolerance to poor adhesion of the legs and enables materials with lower electrical conductivity to be employed as the thermoelectric legs.

The electrical bridge may be formed from at least one of poly(3,4-ethylenedioxythiophene), polyaniline, copper iodide, indium tin oxide, aluminium doped zinc oxide, gallium-doped zinc oxide, aluminium- and gallium-co-doped zinc oxide and fluorine-doped tin oxide. Other materials may be employed in the electrical bridge according to embodiments.

The first material may comprise at least one of poly(3,4-ethylenedioxythiophene), polyaniline and copper iodide, preferably poly(3,4-ethylenedioxythiophene) doped with poly(styrene sulfonate) anions, more preferably poly(3,4-ethylenedioxythiophene) doped with poly(styrene sulfonate) anions and treated with a mixture of trifluoromethanesulfonic acid and methanol. Other materials may be employed as the first material according to embodiments.

The second material may comprise at least one of indium tin oxide, aluminium doped zinc oxide, gallium-doped zinc oxide, aluminium- and gallium-co-doped zinc oxide, fluorine-doped tin oxide, preferably low-temperature indium tin oxide. Other materials may be employed as the second material according to embodiments.

By low-temperature indium tin oxide, it is meant that ITO is deposited onto the substrate at temperatures of less than 60° C.

Any of the above first and second materials may be combined according to embodiments. Materials not listed above may be employed as first and second materials according to embodiments.

The combination of poly(3,4-ethylenedioxythiophene) doped with poly(styrene sulfonate) anions and treated with a mixture of trifluoromethanesulfonic acid and methanol and low-temperature indium tin oxide is preferred because these materials both have high conductivity and permit high transmission of visible light.

The substrate may comprise at least one of glass, polyethylene terephthalate, and polycarbonate. Other materials may be employed as the substrate according to embodiments. Any of these materials may be used with any combination of the first and second materials listed above.

In an aspect, a thermoelectric module is provided, the module comprising: a substrate; a first material of a first doping type forming a first leg extending on the surface of the substrate, the first leg comprising a first end oriented towards a first region of the surface and a second, opposite end oriented towards a second region of the surface; and a second material of a second doping type forming a second leg extending on the surface of the substrate, the second leg comprising a first end oriented towards the first region of the surface and a second, opposite end oriented towards the second region of the surface, such that the first and second legs are substantially parallel to each other, wherein the first end of the first material and the first end of the second material are in electrical connection via a direct interface between the first material and the second material, and wherein the first and second doping types have opposite polarity, such that when a heat flux is applied between the first region and the second region of the surface, a potential difference arises between the second end of the first material and the second end of the second material.

In an aspect, a thermoelectric device is provided, the thermoelectric device comprising a thermoelectric module comprising: a substrate; a first material of a first doping type forming a first leg extending on the surface of the substrate, the first leg comprising a first end oriented towards a first region of the surface and a second, opposite end oriented towards a second region of the surface; and a second material of a second doping type forming a second leg extending on the surface of the substrate, the second leg comprising a first end oriented towards the first region of the surface and a second, opposite end oriented towards the second region of the surface, wherein the first end of the first leg is in electrical connection with the first end of the second leg, and wherein the first and second doping types have opposite polarity, such that when a heat flux is applied between the first region and the second region of the surface, a potential difference arises between the second end of the first leg and the second end of the second leg; a first heat couple plate in thermal connection with the first region of the surface; and a second heat couple plate in thermal connection with the second region of the surface, and wherein one of the heat couple plates is configured to act as a heat source and the other heat couple plate is configured to act as a heat sink.

Thus, the heat couple plates are configured to apply a heat flux between the first region and the second region of the surface.

In an aspect, a thermoelectric generating device is provided, the thermoelectric device comprising an array of interconnected thermoelectric modules, each module comprising: a substrate; a first material of a first doping type forming a first leg extending on the surface of the substrate, the first leg comprising a first end oriented towards a first region of the surface and a second, opposite end oriented towards a second region of the surface; and a second material of a second doping type forming a second leg extending on the surface of the substrate, the second leg comprising a first end oriented towards the first region of the surface and a second, opposite end oriented towards the second region of the surface, wherein the first end of the first leg is in electrical connection with the first end of the second leg, and wherein the first and second doping types have opposite polarity, such that when a heat flux is applied between the first region and the second region of the surface, a potential difference arises between the second end of the first leg and the second end of the second leg.

The modules may share the same substrate. The ends of the legs may all be orientated towards the same regions of the substrate. The device may further comprise a first heat couple plate in thermal connection with a first region of the surface; and a second heat couple plate in thermal connection with a second region of the surface, and wherein one of the heat couple plates is configured to act as a heat source and the other heat couple plate is configured to act as a heat sink.

The thermoelectric device may comprise a series of alternating n- and p-legs in spaced parallel arrangement.

### BRIEF DESCRIPTION OF THE DRAWINGS

Embodiments are described below in association with the figures, in which:

FIG. 1 shows a conventional bulk thermoelectric device;

FIG. 2 shows a thermoelectric device according to an embodiment;

FIG. 3 shows the thermoelectric device according to FIG. 3 with heat couple plates;

FIGS. 4(a) and 4(b) show the electrical conductivity and Seebeck coefficient of several thermoelectric materials, respectively;

FIGS. 5(a) and 5(b) show the conductivity and power function of thermoelectric materials, respectively;

FIG. 6 shows a thermoelectric device according to an embodiment; and

FIG. 7 shows the output voltage and output power of thermoelectric elements produced in accordance with embodiments.

### DETAILED DESCRIPTION

For purposes of brevity and clarity, descriptions of embodiments of the present disclosure are directed to a thermoelectric module, in accordance with the drawings. While aspects of the present disclosure will be described in conjunction with the embodiments provided herein, it will be understood that they are not intended to limit the present disclosure to these embodiments. On the contrary, the present disclosure is intended to cover alternatives, modifications and equivalents to the embodiments described herein, which are included within the scope of the present disclosure as defined by the appended claims. Furthermore, in the following detailed description, specific details are set forth in order to provide a thorough understanding of the present disclosure. However, it will be recognized by an individual having ordinary skill in the art, i.e. a skilled person, that the present disclosure may be practiced without specific details, and/or with multiple details arising from combinations of aspects of particular embodiments. In a number of instances, well-known systems, methods, procedures, and components have not been described in detail so as to not unnecessarily obscure aspects of the embodiments of the present disclosure.

In embodiments of the present disclosure, depiction of a given element or consideration or use of a particular element number in a particular figure or a reference thereto in corresponding descriptive material can encompass the same, an equivalent, or an analogous element or element number identified in another figure or descriptive material associated therewith.

References to “an embodiment/example”, “another embodiment/example”, “some embodiments/examples”, “some other embodiments/examples”, and so on, indicate that the embodiment(s)/example(s) so described may include a particular feature, structure, characteristic, property, element, or limitation, but that not every embodiment/example necessarily includes that particular feature, structure, characteristic, property, element or limitation. Furthermore, repeated use of the phrase “in an embodiment/example” or “in another embodiment/example” does not necessarily refer to the same embodiment/example.

The terms “comprising”, “including”, “having”, and the like do not exclude the presence of other features/elements/steps than those listed in an embodiment. Recitation of certain features/elements/steps in mutually different embodiments does not indicate that a combination of these features/elements/steps cannot be used in an embodiment.

As used herein, the terms “a” and “an” are defined as one or more than one. The use of “I” in a figure or associated text is understood to mean “and/or” unless otherwise indicated. The term “set” is defined as a non-empty finite organization of elements that mathematically exhibits a cardinality of at least one (e.g. a set as defined herein can correspond to a unit, singlet, or single-element set, or a multiple-element set), in accordance with known mathematical definitions. The recitation of a particular numerical value or value range herein is understood to include or be a recitation of an approximate numerical value or value range.

FIG. 2 shows a schematic of a thermo-electric generator 200 according to an embodiment. The thermoelectric generator 200 comprises a substantially planar substrate 201, on the surface of which a first material 203 and a second material 205 are arranged. Portions of first material 203 and second material 205 are arranged such that they extend across the surface of the substrate 201 in parallel directions, in this case in alternating periodic array of parallel elongate portions, or legs.

In an embodiment, the first 203 and second 205 materials are n- and p-type materials, respectively. In an embodiment, the n-type and p-type materials are thin-film materials. Thus, the overall profile of the thermoelectric generator is substantially planar.

By thin-film, it is meant that the thickness of the layer of material deposited on the substrate is on the nano-scale, preferably less than 500 nm in thickness.

Note that while only a small number of n- and p-legs are shown in FIG. 2, the skilled person will appreciate that FIG. 2 is merely intended to represent one particular arrangement and that greater or lesser numbers of alternating legs may be employed according to embodiments.

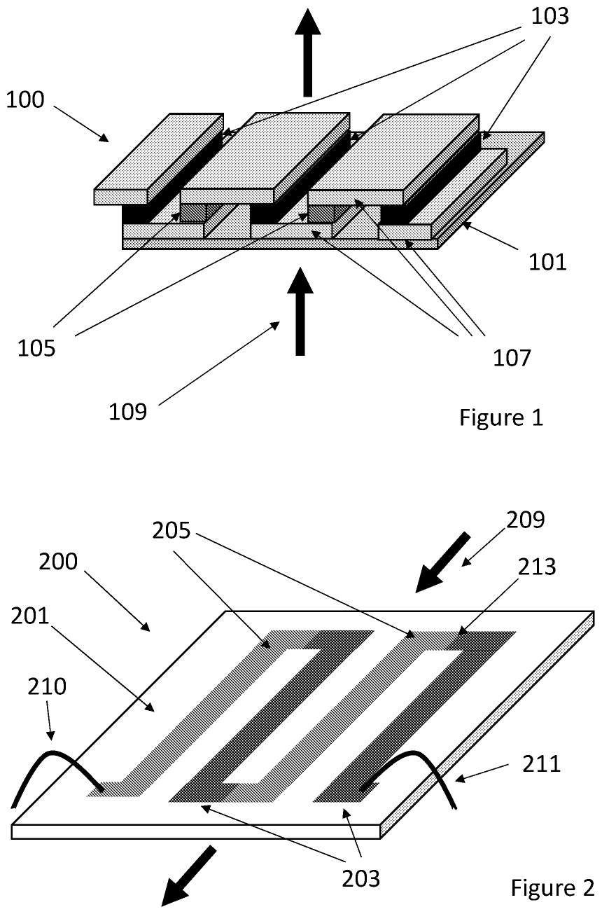

In the embodiment of FIG. 2, there is a head to head connection 213 between the p- and n-type thermoelectric legs, i.e. there is a direct interface between the p- and n-type legs. Note that this contrasts with the conventional example of FIG. 1, where there is no direct interface between the p- and n-type legs. This will be discussed further below.

The module 200 further comprises a pair of electrodes 210, 211 in electrical contact at either end of the module with the outer n- and p-type legs, respectively. In an embodiment, a pair of heat couple plates are positioned orthogonally to the substrate 201 and connected to a heat source and heat sink respectively. Thus, when a such heat flux is applied across the plane of the substrate as shown by the arrow 209, electron flow is stimulated in the p- and n-type legs due to the Seebeck effect described above, such that a potential difference is generated across the electrodes 211, thereby resulting in thermoelectric generation.

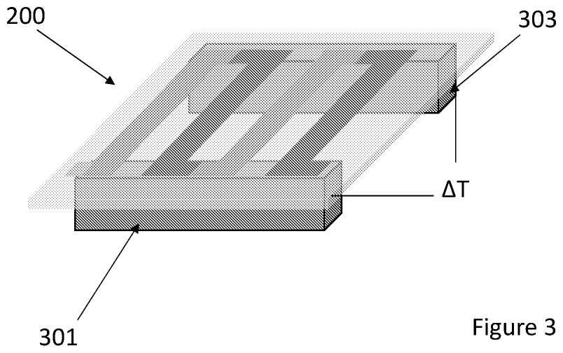

FIG. 3 shows a schematic of the thermoelectric generator 200 of FIG. 2, showing the position of heat couple plates 301 and 303 according to an embodiment. The skilled person will appreciate that different configurations of the heat couple plates are possible according to embodiments.

One of the heat couple plates 301, 303 is configured to act as a heat source and one as a heat sink. Thus, via the heat couple plates, a temperature difference ΔT is applied across the plates, and a potential difference is generated across the device between n- and p-legs due to the Seebeck effect, as described above.

In an embodiment, each of the heat couple plates has a temperature in the range 0-150° C. In an embodiment, the temperature difference between the heat source and the heat sink is between 1-100° C.

In order to achieve a suitable potential difference across the electrodes, preferably, the thermal conductivity of the thermoelectric p and n-type film is in the range 0.1-10 uW/mK.

As will be clear to the person skilled in the art, the p- and n-type legs of the module 200 are connected thermally in parallel but electrically in series.

Thus, the thermoelectric module of the embodiment of FIGS. 2 and 3 acts an in-plane thermoelectric generator, i.e. electricity generation occurs when a heat flux is applied parallel to the plane of the substrate. Note that this contrasts with the thermoelectric generator of FIG. 1, in which vertical heat flux, i.e. orthogonal to the plane of the substrate, is required for thermoelectric generation to occur.

As noted above, the n- and p-type legs of the embodiment of FIG. 2 are connected via a head to head, or a direct interface, connection. Such head to head connection is advantageous because it enables straightforward manufacture of the device, without the need for bridging material. However, head to head connection is difficult to achieve using the 3-D bulk structure of the design of the thermoelectric generator of FIG. 1. In contrast the substantially planar, substantially two-dimensional structure of thermoelectric generators according to embodiments facilitates the implementation of a head to head design.

In order to ensure adequate electrical connection between legs 203 and 205 via the head-to-head interface 213, n- and p-type materials with high electrical conductivity must be employed in the embodiment of FIG. 2.

Preferably the electrical conductivity of the p and n-type films is in the range 100-10000 S/cm.

In an embodiment, the thin-film module 200 is substantially transparent to visible light. In this embodiment, p- and n-type thermoelectric films with both high transmittance of light in the visible range and high electrical conductivity are employed as p- and n-type materials in the embodiments of FIGS. 2 and 3. In combination with a transparent substrate 201, this enables the provision of a transparent thermoelectric module 200 according to an embodiment. Preferably, the visible light transmittance of the p and n-type films is over 50%.

The substantially planar profile of the thermoelectric generator of FIG. 2 facilitates the provision of a substantially transparent device because materials may be employed which permit transmittance of visible light at nano-scale thicknesses but which may become opaque as the thickness of the material increases. In the conventional 3-D design of FIG. 1, in which bulk semiconductor materials are employed, transparency is difficult to achieve.

Suitable p-type transparent materials with high electrical conductivity for use in the embodiment of FIG. 2 include, but are not limited to, conducting polymers such as poly(3,4-ethylenedioxythiophene) (PEDOT), polyaniline, etc., and organic conducting molecules and inorganic transparent materials like Cul thin-film, etc.

All of the above listed materials are commercially available in forms suitable for thin-film deposition.

Suitable n-type transparent materials include, but are not limited to, ITO, aluminum doped zinc oxide (AZO), gallium-doped zinc oxide (GZO), Al- and Ga-co-doped ZnO (AGZO), fluorine-doped tin oxide (FTO) and other n-type organic or hybrid thermoelectric thin films.

All of the above listed materials are commercially available in forms suitable for thin-film deposition.

The above materials are both substantially transparent to visible light at thin-film thicknesses and are sufficiently electrically conductive to enable direct head-to-head connection between legs with only small current loss at the connection. Other materials not listed above may be employed according to embodiments.

In an embodiment, either a transparent rigid substrate such as glass or a flexible transparent substrate including, but not limited to, polyethylene terephthalate (PET), polycarbonate (PC), etc. is employed as the substrate 201.

The thickness of the substrate is not particularly limited and can be varied according to flexibility, size and durability requirements. For example, thinner substrates will generally result in a greater flexibility overall but may correspond to reduced durability.

In an embodiment, poly(3,4-ethylenedioxythiophene) doped with poly(styrene sulfonate) anions (PEDOT:PSS) thin-films are employed as p-type thermoelectric legs. In another embodiment, indium tin oxide (ITO) is employed as n-type thermoelectric legs. In an embodiment, these two materials are employed together. The combination of these two materials is advantageous as it ensures large electrical energy generation for a given heat flux, i.e. a large Seebeck coefficient.

In an embodiment, an ITO film with a thickness in the range 10-500 nm, is employed as the n-type thermoelectric legs. In an embodiment, a PEDOT:PSS film with a thickness in the range 20-500 nm is employed as the p-type thermoelectric legs.

In an embodiment, treated PEDOT:PSS thin-films are employed as p-type thermoelectric legs. In embodiments, the PEDOT:PSS thin films are treated with one or more of DMSO, methanol (MeOH) and trifuoromethanesulfonic acid (CF₃SO₃H) or a mixture thereof. Preferably, PEDOT:PSS thin films treated with a mixture of trifuoromethanesulfonic acid and methanol (TFMS-MeOH) are employed as p-type thermoelectric legs.

In an embodiment, treating a film with a liquid, as described above, comprises dropping the relevant liquid onto the pristine film and then allowing the film to dry.

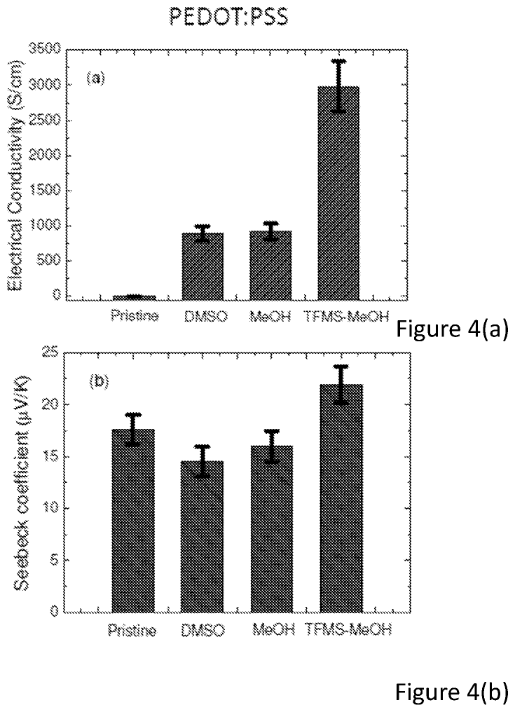

Treated PEDOT:PSS thin-films are advantageous as they have a high electrical conductivity and, in some cases, Seebeck coefficient. FIG. 4(a) shows the electrical conductivity of PEDOT:PSS thin films without treatment (pristine), following treatment with DMSO, following treatment with MeOH and following treatment with TFMS-MeOH. The results show that all of the treated films have increased electrical conductivity relative to the pristine films, with TFMS-MeOH showing the greatest improvement.

FIG. 4(b) shows corresponding values of the Seebeck coefficient for the pristine and treated films. While treatment with DMSO and MeOH results in a decrease in Seebeck coefficient, treatment with TFMS-MeOH results in an improved Seebeck coefficient relative to the untreated (pristine) film.

In an embodiment, low-temperature indium tin oxide (LT-ITO) is employed in the n-type legs. In an embodiment, this comprises depositing ITO onto the substrate at temperatures of less than 60° C.

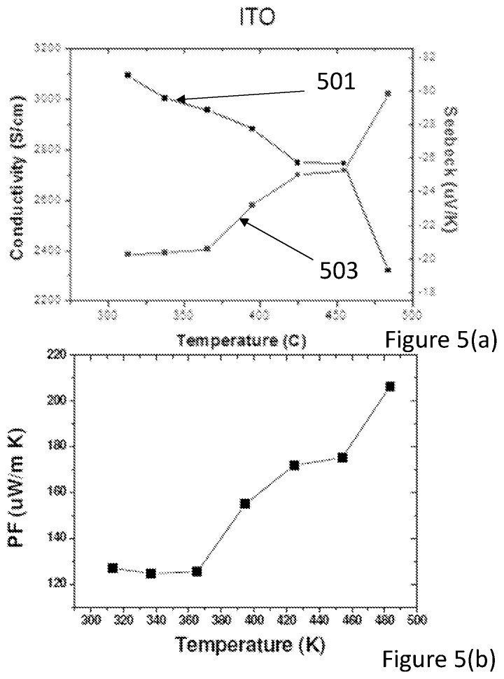

FIGS. 5(a) and 5(b) show the conductivity 501 and Seebeck coefficient 503, and Power functions, respectively of LT-ITO films as a function of temperature.

Table 1 shows a comparison between the properties of commercially available ITO and pristine PEDOT:PSS and their low-temperature and TFMS-MeOH treated counterparts, respectively.

TABLE 1

| | | | TFMS-MeOH | Low- |
|---|---|---|---|---|
| Thermoelectric | Pristine | | treated | temperature |
| Properties | PEDOT:PSS | ITO | PEDOT:PSS | ITO |
| Seebeck | 17.6 | −8.25 | 21.9 | −20.3 |
| (μV/K) | | | | |
| Condutivity | 0.69 | 6419 | 2980 | 3094 |
| (S/cm) | | | | |
| PF(μW/mK²) | 0.022 | 43.8 | 143 | 127 |

Clearly, TFMS-MeOH treated PEDOT:PSS and Low-temperature ITO perform their pristine and normal counterparts.

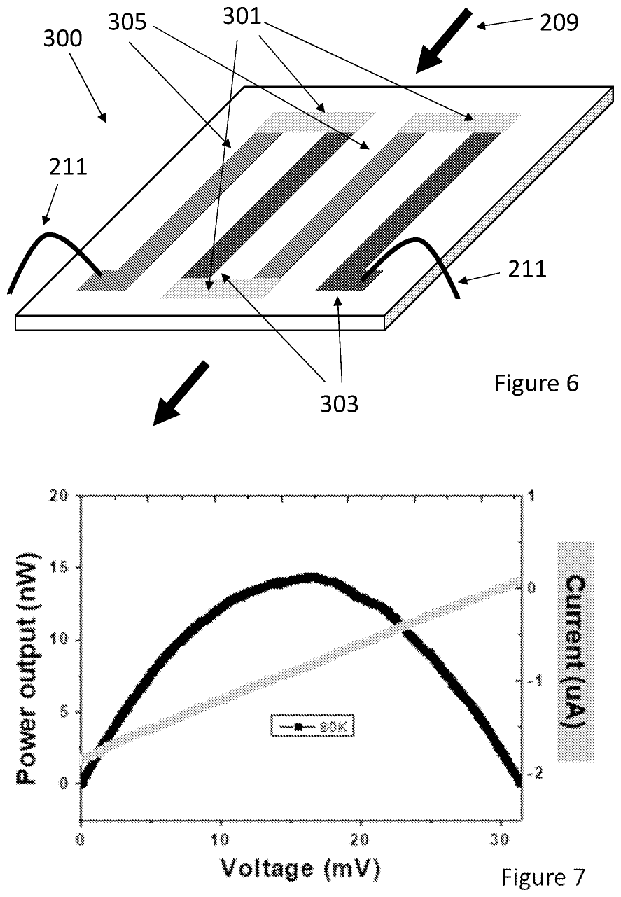

FIG. 6 shows a schematic of thermo-electric generator 300 according to another embodiment. In this embodiment, as in the embodiment of FIG. 2, the thermoelectric generator 300 comprises a substantially planar substrate 201, on the surface of which an alternating periodic array of n-type 303 and p-type 305 thin film legs are arranged. In this embodiment, in contrast to that of FIG. 2, the n- and p-type thermoelectric legs are connected using conductive thin films 301 which are also arranged on the surface of the substrate 301 and which act as contact bridges between the n- and p-type thermoelectric legs.

Note that while only a small number of n- and p-legs are shown in FIG. 6, the skilled person will appreciate that FIG. 6 is merely intended to be representative of the arrangement and that greater or fewer numbers of alternating legs may be employed according to embodiments.

The module 300 further comprises a pair of electrodes 210, 211 in electrical contact at either end of the module with n- and p-type legs, respectively. In an embodiment, a pair heat couple plates (not shown) are positioned orthogonally to the substrate 201 and connected to a heat source and heat sink respectively. Thus, when a heat flux is applied across the plane of the substrate as shown by the arrow 209, electron flow is stimulated in the p- and n-type legs due to the Seebeck effect described above. A potential difference is then generated across the electrodes 211, thereby resulting in thermoelectric generation.

Thus, in common with the embodiment of FIG. 2, the thermoelectric module of the embodiment of FIG. 6 acts an in-plane thermoelectric generator, i.e. electricity generation occurs when a heat flux is applied parallel to the plane of the substrate.

However, unlike the embodiment of FIG. 2, there is no head to head connection between the n- and p-type films. The embodiment of FIG. 6 therefore can be employed when good connection between the n and p-type films cannot be ensured, for example for films without good adhesion. Instead, the conductive film 301 provides a strong electrical connection between the n and p type films.

In an embodiment, the thermoelectric module 300 is also transparent. As well as a transparent substrate 201, and n- and p-legs 303 and 305, respectively, the module 300 according to an embodiment comprises transparent thin-film contact bridges 301.

In the embodiment, of FIG. 6, because the n- and p-type legs are in electrical contact via contact bridges 301 and are not in head to head contact as in the embodiment of FIG. 2, the electrical conductivity requirements of the n- and p-type thin-film material are less stringent than for the embodiment of FIG. 2.

Therefore, in addition to the n- and p-type transparent materials described above in relation to the embodiment of FIG. 2, other suitable materials for use in the n-type legs include (but are not limited to) transparent materials such as AZO, GZO, AGZO, FTO, and n-type graphene, carbon nanotubes (CNT), and carbon nanowalls (CNW) or a mixture thereof.

Additional suitable materials for use in the p-type legs include (but are not limited to) transparent materials polyaniline, Cul thin-film, p-type organic doping polymer.

Note in particular that some p-type polymers and n-type graphene/CNT/CNW typically have poor adhesion are therefore not suitable for use in the embodiment of FIG. 2 as they would not ensure sufficient electrical connection for use in a head to head configuration.

In an embodiment, the electrode bridge 301 comprises a material with high electrical conductivity. In an embodiment, the electrode bridge 301 comprises a substantially transparent material with high electrical conductivity.

In an embodiment, the transparent electrode bridge 301 comprises one or more of the above described p- or n-type materials, including, but not limited to conducting polymers such as PEDOT, PEDOT:PSS, PEDOT:PSS treated with TFMS-MeOH, and polyaniline; organic conducting molecules and inorganic transparent materials, such as Cul thin-film; ITO, Low-temperature ITO, aluminum doped zinc oxide (AZO), gallium-doped zinc oxide (GZO), Al- and Ga-co-doped ZnO (AGZO), fluorine-doped tin oxide (FTO) and other n-type organic or hybrid thermoelectric thin films.

In an embodiment, either a transparent rigid substrate such as glass or a flexible substrate including polyethylene terephthalate (PET), polycarbonate (PC), etc. may be employed as the substrate 201.

Fabrication techniques employed in the production of the embodiments of FIGS. 2 and 6 may include thin film printing techniques and thin film deposition technologies.

The thin film n- and p-layers and, where appropriate, the conductive bridges in the modules of the embodiments of FIGS. 2 and 6 may be deposited on the substrate using any suitable technique which achieves an appropriate thickness, such as thin film printing and thin film deposition. Examples include but are not limited to spray-coating, spin-coating, drop-casting, blade coating, roll to roll and other thin film printing methods, atomic layer deposition (ALD), sputtering, chemical vapor deposition (CVD), plasma vapor deposition (PVD) and thermal evaporation nano-thin film fabrication methods. All of these methods are well known in the art.

In an embodiment, a thickness preferably in the range 10-500 nm is achieved by the thin film fabrication printing/deposition method employed. This ensures a substantially two-dimensional profile of the thermoelectric generator and enables transparency due to the thin materials.

Treatments applied to the p- and n-type thin films according to embodiments may include doping, post-treatment and annealing processes in order to obtain optimized thermoelectric performance according to requirements.

In an embodiment, the p-type layers may comprise PEDOT:PSS thin films deposited on the substrate using the spin-coating method or the blade-coating method. In a further embodiment, the PEDOT:PSS thin films are treated a mixture of trifuoromethanesulfonic acid and methanol (TFMS-MeOH) after being spin-coated onto the substrate. In an embodiment, this comprises dropping a mixture of trifuoromethanesulfonic acid and methanol (TFMS-MeOH) onto the film and then allowing the film to dry.

In an embodiment, the n-type layer may be fabricated by sputtering ITO in a vacuum chamber at different gas partial pressures. In an embodiment, this sputtering is performed at low temperatures of less than 60° C.

In other embodiments, the PEDOT:PSS thin film may be replaced by other p-type transparent organic and inorganic thermoelectric films, and the LT-ITO thin film may be replaced by other transparent organic and inorganic n-type thermoelectric thin films, as described above according to embodiments.

In an embodiment, the substrate comprises plastic film and thin film deposition of the n- and p-legs and (where relevant) and the contact bridges is performed at temperatures of less than 150° C. This ensures that the resulting device is flexible.

### EXAMPLE

A prototype of a transparent thermoelectric thin-film module according to an embodiment was fabricated, consisting of pairs of thermoelectric legs of PEDOT:PSS and LT (low-temperature) ITO thin-films deposited on a glass substrate or a PET substrate. The p- and n-type thermoelectric legs were head to head connected, in accordance with the embodiment of FIG. 2. A 60-nm thick PEDOT:PSS film coated on the glass was employed for the p-type thermoelectric leg. This was prepared by spin-coating or blade coating the substrate with commercially available PEDOT:PSS. A mixture of trifluoromethanesulfonic acid (CF3SO3H) and methanol (CH3OH) in a volume to volume ratio of 1:10 followed by pure methanol was used to treat the PEDOT:PSS films. In detail, 200 μL liquid (CF3SO3H/CH3OH) was dropped onto the PEDOT:PSS thin films at 130° C. The film was dried for about 30 min, and then the dried films were washed by dropping methanol onto the films for three times. Post treated PEDOT:PSS films with a thickness of 60 nm showed a high electrical conductivity of 2900 S/cm and an average transmittance of more than 85%.

An ITO anode which was formed at a low process temperature of less than 60° C. was deposited onto the glass surface as n-type thermoelectric legs. Commercially available ITO was sputtered in a vacuum at temperatures of less than 60° C. ITO film produced in this way with a thickness of 130 nm exhibited a sheet resistance of 25±5 Ω/sq and an average transmittance of above 85%.

The output voltage and output power of the thermoelectric elements produced in accordance with above are shown in FIG. 7 for a temperature difference of 80 K. Ten pairs of p- and n-type thermoelectric legs were connected in series and the output I-V and output power-V characteristics were studied. The current-voltage characteristic (grey line) of the thermoelectric element was linear, as can be seen in FIG. 7. The output power (black curve) is described by the equation Pₒᵤₜ=S ΔTI−I²Rᵢₙₜ. The device generated a maximum power output of 14.4 nW at ΔT=80K, and the corresponding power density was estimated to be 22.2 W/m².

Thus, the thermoelectric devices according to the above described embodiments are small, ultra thin, ultra light, flexible thermoelectric devices, and have a high thermoelectric performance.

Modules according to the above described embodiments could be employed in smart windows (or screens) with energy harvesting, cooling, and thermal sensing functionalities. They could be easily integrated in various electronic devices, and find many other potential applications, including, but not limited to fast on-chip cooling and power recovery for optoelectronic devices including solar cells, infrared photodetectors as well as transparent electronic devices, such as wearable devices.

In the foregoing detailed description, embodiments of the present disclosure in relation to a thermoelectric module are described with reference to the provided figures. The description of the various embodiments herein is not intended to call out or be limited only to specific or particular representations of the present disclosure, but merely to illustrate non-limiting examples of the present disclosure. The present disclosure serves to address at least one of the mentioned problems and issues associated with the prior art. Although only some embodiments of the present disclosure are disclosed herein, it will be apparent to a person having ordinary skill in the art in view of this disclosure that a variety of changes and/or modifications can be made to the disclosed embodiments without departing from the scope of the present disclosure. Therefore, the scope of the disclosure as well as the scope of the following claims is not limited to embodiments described herein.

1. A thermoelectric module comprising:
a substrate;
a first material of a first doping type forming a first leg extending on a surface of the substrate, the first leg comprising a first end oriented towards a first region of the surface and a second, opposite end oriented towards a second region of the surface; and
a second material of a second doping type forming a second leg extending on the surface of the substrate, the second leg comprising a first end oriented towards the first region of the surface and a second, opposite end oriented towards the second region of the surface, such that the first and second legs are substantially parallel to each other,
wherein the first end of the first leg is in electrical connection with the first end of the second leg, and
wherein the first and second doping types have opposite polarity,
such that when a heat flux is applied between the first region and the second region of the surface, a potential difference arises between the second end of the first leg and the second end of the second leg, and
wherein the substrate, the first material, and the second material are substantially transparent to visible light.

2. The thermoelectric module of claim 1, wherein the first end of the first leg and the first end of second leg are in electrical connection via a direct interface or an electrical bridge between the first material and the second material.

3. (canceled)

4. The thermoelectric module of claim 2, wherein the electrical bridge is substantially transparent to visible light.

5. The thermoelectric module of claim 4, wherein the electrical bridge is formed from at least one of poly(3,4-ethylenedioxythiophene), polyaniline, copper iodide, indium tin oxide, aluminium doped zinc oxide, gallium-doped zinc oxide, aluminium- and gallium-co-doped zinc oxide and fluorine-doped tin oxide.

6. The thermoelectric module of claim 1, the thermoelectric module having a visible light transmittance of greater than 50%.

7. A thermoelectric module comprising:
a substrate;
a first material of a first doping type forming a first leg extending on the surface of the substrate, the first leg comprising a first end oriented towards a first region of the surface and a second, opposite end oriented towards a second region of the surface; and
a second material of a second doping type forming a second leg extending on the surface of the substrate, the second leg comprising a first end oriented towards the first region of the surface and a second, opposite end oriented towards the second region of the surface, such that the first and second legs are substantially parallel to each other,
wherein the first end of the first material and the first end of the second material are in electrical connection via a direct interface between the first material and the second material, and
wherein the first and second doping types have opposite polarity,
such that when a heat flux is applied between the first region and the second region of the surface, a potential difference arises between the second end of the first material and the second end of the second material.

8. The thermoelectric module of claim 1, wherein the first material comprises at least one of poly(3,4-ethylenedioxythiophene), polyaniline and copper iodide.

9. (canceled)

10. The thermoelectric module of claim 8, wherein the first material comprises poly(3,4-ethylenedioxythiophene) doped with poly(styrene sulfonate) anions and optionally treated with a mixture of trifluoromethanesulfonic acid and methanol.

11. The thermoelectric module of claim 1, wherein the second material comprises at least one of indium tin oxide, low-temperature indium tin oxide, aluminium doped zinc oxide, gallium-doped zinc oxide, aluminium- and gallium-co-doped zinc oxide, and fluorine-doped tin oxide.

12. (canceled)

13. The thermoelectric module of claim 1, wherein the substrate comprises at least one of glass polyethylene terephthalate, and polycarbonate.

14. (canceled)

15. The thermoelectric module of claim 1, further comprising:
a first heat couple plate in thermal connection with the first region of the surface; and
a second heat couple plate in thermal connection with the second region of the surface, and
wherein one of the heat couple plates is configured to act as a heat source and the other heat couple plate is configured to act as a heat sink.

16. A thermoelectric generating device comprising an array of interconnected thermoelectric modules according to claim 1.

17. A method of producing a thermoelectric module according to claim 1, the method comprising depositing the first and second materials on the surface of the substrate using at least one of spray-coating, spin-coating, drop-casting, blade coating, roll to roll and other thin film printing methods, atomic layer deposition (ALD), sputtering, chemical vapor deposition (CVD), plasma vapor deposition (PVD) and thermal evaporation nano-thin film fabrication methods.

18. The thermoelectric module of claim 7, wherein the first material comprises at least one of poly(3,4-ethylenedioxythiophene), polyaniline and copper iodide.

19. The thermoelectric module of claim 18, wherein the first material comprises poly(3,4-ethylenedioxythiophene) doped with poly(styrene sulfonate) anions and optionally treated with a mixture of trifluoromethanesulfonic acid and methanol.

20. The thermoelectric module of claim 7, wherein the second material comprises at least one of indium tin oxide, low-temperature indium tin oxide, aluminium doped zinc oxide, gallium-doped zinc oxide, aluminium- and gallium-co-doped zinc oxide, and fluorine-doped tin oxide.

21. The thermoelectric module of claim 7, wherein the substrate comprises at least one of glass polyethylene terephthalate, and polycarbonate.

22. The thermoelectric module of claim 7, further comprising:
a first heat couple plate in thermal connection with the first region of the surface; and
a second heat couple plate in thermal connection with the second region of the surface, and
wherein one of the heat couple plates is configured to act as a heat source and the other heat couple plate is configured to act as a heat sink.

23. A thermoelectric generating device comprising an array of interconnected thermoelectric modules according to claim 7.

24. A method of producing a thermoelectric module according to claim 7, the method comprising depositing the first and second materials on the surface of the substrate using at least one of spray-coating, spin-coating, drop-casting, blade coating, roll to roll and other thin film printing methods, atomic layer deposition (ALD), sputtering, chemical vapor deposition (CVD), plasma vapor deposition (PVD) and thermal evaporation nano-thin film fabrication methods.
